(19) United States
(12) Patent Application Publication
(10) Pub. No.: US 2009/0067108 A1
(43) Pub. Date: Mar. 12, 2009

(54) CLOSING RESISTOR FOR HIGH-VOLTAGE CIRCUIT BREAKERS

(75) Inventors: Urs Kruesi, Zurich (CH); Rene Freidinger, Bayreuth (DE); Walter Holaus, Zurich (CH); Markus Keller, Zurich (CH)

Correspondence Address: BUCHANAN, INGERSOLL & ROONEY PC, POST OFFICE BOX 1404, ALEXANDRIA, VA, 22313-1404, US

(73) Assignee: ABB Technology AG, Zurich (CH)

(21) Appl. No.: 12/206,769

(22) Filed: Sep. 9, 2008

(30) Foreign Application Priority Data
Sep. 10, 2007 (EP) 07116030.3

(51) Int. Cl. H02H 9/00; H05K 7/20

(52) U.S. Cl. 361/58; 361/722

(57) ABSTRACT

A closing resistor arrangement for a high-voltage circuit breaker has a large number of resistor elements and a large number of cooling elements, the cooling elements being arranged in series with one another and being connected electrically in series with one another. The resistor elements, which electrically connect the electrical cooling elements to one another, are arranged between in each case two cooling elements which are arranged in series.

### RELATED APPLICATION

This application claims priority under 35 U.S.C. 119 to European Patent Application No. 07116030.3 filed in Europe on Sep. 10, 2007, the entire content of which is hereby incorporated by reference in its entirety.

### TECHNICAL FIELD

The disclosure relates to a closing resistor arrangement and to a high-voltage circuit breaker with such a closing resistor arrangement.

### BACKGROUND INFORMATION

A high-voltage circuit breaker with a closing resistor arrangement is known from WO 93/02461. The known high-voltage circuit breaker has a tubular housing filled with insulating gas, which is at ground potential. A high-voltage bushing is arranged on the housing at both end regions of the high-voltage circuit breaker. An interrupter unit and the closing resistor arrangement are arranged and connected in series with one another between the two high-voltage bushings within the housing, in the direction of the longitudinal axis. In order, once the high-voltage circuit breaker has closed, to isolate the closing resistors of the closing resistor arrangement from the circuit, the closing resistor arrangement has a current path which is routed in parallel with the closing resistors and is closed with or shortly after the closing of the interrupter unit.

The known closing resistor arrangement has a large number of resistor elements which are connected in series with one another and which are arranged on two insulating bars running parallel to one another. The electrical connection between the resistor elements is produced via electrodes, which connect substantially adjacent resistor elements on the two insulating bars to one another. This means that the current path is routed in meandering fashion through the resistor arrangement and therefore the resistor elements which are arranged mechanically parallel to one another and adjacent to one another are connected electrically in series with one another.

One disadvantage with this arrangement has proven to be the fact that, owing to the very compact design of this closing resistor arrangement, the lost heat from the resistor elements can be dissipated poorly. This results in the problem that the known circuit breaker, during a certain time span after a first closing operation and a subsequent opening operation, cannot be closed a second time within the time span because otherwise this could result in overheating of the closing resistor arrangement. This problem is in particular intensified further if the system is changed over to a higher mains voltage since the equation P=U²/R (U: voltage; R: resistance) applies for the power P of the electrical current.

A further electrical resistor arrangement is known from FR 940 438. This known resistor arrangement has a variable number of resistor elements carried on a support tube. In order to increase the cooling of the resistor elements, metal plates are arranged between the resistor elements. A similar resistor arrangement is also known from U.S. Pat. No. 2,870,307.

From EP 0 041 470 a further, stacked resistor arrangement particularly for high-voltage installations is known.

### SUMMARY

An improved closing resistor arrangement is disclosed along with a circuit breaker with such a closing resistor arrangement. For example, the intention is to provide a closing resistor or a high-voltage circuit breaker which allows for multiple switching even at relatively high voltages of the power supply system.

A closing resistor arrangement for a high voltage circuit breaker is disclosed with a large number of resistor elements and a large number of connecting elements, the connecting elements being arranged in series with one another and at least one of the resistor elements being arranged between at least two connecting elements which are arranged in series for the serial electrical connection of these connecting elements. The connecting elements which are electrically connected to one of the resistor elements are in the form of a cooling element for the purpose of dissipating heat from the resistor element. Two cooling elements which are arranged in series with one another are electrically connected to one another by means of a resistor element and wherein a plurality of resistor elements are arranged parallel to one another between two cooling elements and are connected electrically in parallel with one another by the cooling elements.

In another aspect, a closing resistor arrangement for a high voltage circuit breaker is disclosed, comprising: a plurality resistor elements; and a plurality of cooling elements, the cooling elements being arranged in series with one another and being connected electrically in series with one another, wherein the resistor elements electrically connect the electrical cooling elements to one another.

### BRIEF DESCRIPTION OF THE DRAWINGS

The subject matter of the disclosure will be explained in more detail below with reference to an exemplary embodiment. In the drawing, in each case purely schematically:

FIG. 1 shows a high-voltage circuit breaker according to the disclosure with a first housing part with an interrupter unit arranged therein and a second housing part with a closing resistor arrangement according to the disclosure arranged therein which is connected in parallel with the interrupter unit;

FIG. 2 shows a circuit diagram of the high-voltage circuit breaker according to the disclosure as shown in FIG. 1;

FIG. 3 shows, partially in a sectional illustration (longitudinal section), the closing resistor arrangement shown in FIG. 1;

FIG. 4 shows a view of a cooling element and five resistor elements of the closing resistor arrangement according to the disclosure; and

FIG. 5 shows the cooling element and two resistor elements in cross section along the section V-V shown in FIG. 4.

The reference symbols used in the figures and their significance are listed by way of summary in the list of reference symbols. In principle, identical or functionally identical parts have been provided with the same or similar reference symbols in the figures. Some of the parts which are not essential to the understanding of the disclosure are not illustrated. The exemplary embodiment described represents, by way of example, the subject matter of the disclosure and has no restrictive effect.

### DETAILED DESCRIPTION

According to an exemplary embodiment, the closing resistor arrangement has a large number of cooling elements, which dissipate heat from the resistor elements of the closing resistor arrangement. This means that the resistor elements heated by a closing operation of a high-voltage circuit breaker are cooled effectively and therefore do not overheat during a further closing operation. A plurality of resistor elements are arranged parallel to one another between two cooling elements and are connected electrically in parallel with one another via the cooling elements. As a result, a particularly compact design of the closing resistor arrangement can be realized. A cooling element is used firstly for cooling the adjoining resistor elements and secondly for electrically connecting the resistor elements which are arranged parallel to one another.

In accordance with another exemplary embodiment, the cooling elements are flat and protrude beyond a contact region, within which the resistor elements are thermally connected to the cooling element, and beyond this resistor element. The contact region ensures that the heat can flow away from the resistor element onto the cooling element. The flat design of the cooling element means that there is a large surface area in comparison with the total volume of the cooling element, as a result of which the heat can be emitted efficiently from the resistor element via the cooling element.

In accordance with yet another exemplary embodiment, the cooling element has a substantially round shape which is planar within an outer marginal region, the marginal region being curved out of the plane of the central region. This means that the electrical field caused by the closing resistor arrangement is as homogeneous as possible, as a result of which a compact circuit breaker with the closing resistor arrangement according to the disclosure can be realized. In addition, the resistor elements which are arranged between two adjacent cooling elements are shielded.

In accordance with yet another exemplary embodiment, the closing resistor arrangement has an active group. By means of the rods of the active group which are arranged parallel to one another and are supported in each case at their two end regions on both sides by support plates, the cooling elements and the resistor elements are connected mechanically to one another. As a result of the parallel arrangement of a plurality of resistor elements, the power of the current is distributed among a plurality of resistor elements.

In accordance with yet another exemplary embodiment, the interrupter unit and the closing resistor arrangement are arranged in each case within a dedicated housing part. As a result, a particularly compact configuration can be achieved since the shape of the first housing part can be matched to the shape of the interrupter unit and the shape of the second housing part can be matched to the shape of the closing resistor arrangement.

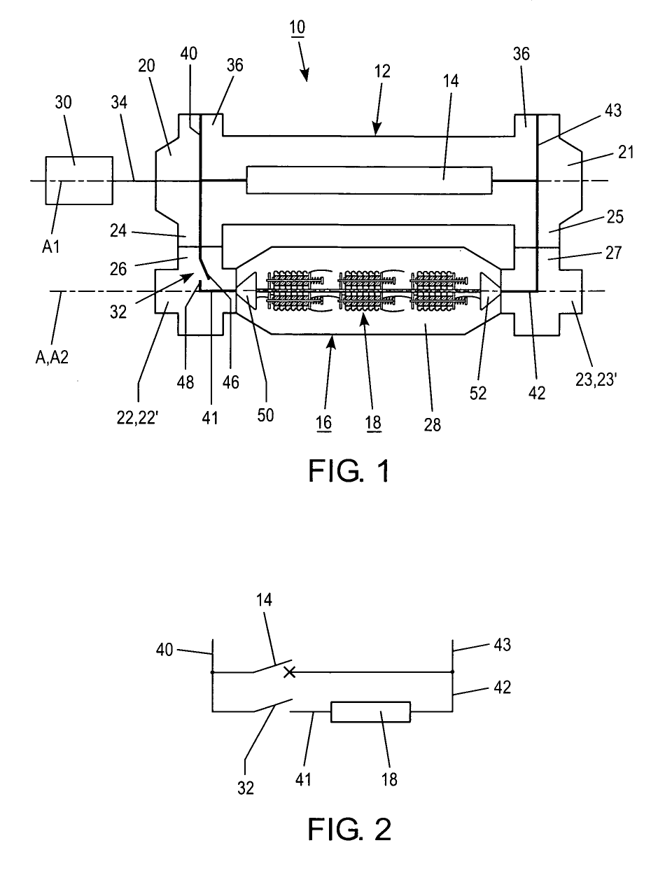

FIG. 1 shows an exemplary metal-encapsulated high-voltage circuit breaker 10 for a gas-insulated switchgear assembly. The circuit diagram of the high-voltage circuit breaker is shown in FIG. 2. In gas-insulated switchgear assemblies, sulfur hexafluoride (SF₆) is used, for example, as the insulting gas. Instead of this gas, another gas with good insulating properties can also be used. Such high-voltage circuit breakers are used for switching currents in mains systems of over 400 kV (kilovolts), in particular of over 800 kV.

The high-voltage circuit breaker 10 according to the disclosure can also be used, instead of in a gas-insulated switchgear assembly, in a hybrid switchgear assembly, in which elements of gas-insulated switchgear assembly construction technology are combined with elements of air-insulated switchgear assembly construction technology.

The high-voltage circuit breaker 10 has a first housing part 12, in which an interrupter unit 14 is arranged, and, parallel to the first housing part 12, a second housing part 16, in which a closing resistor arrangement 18 is arranged. The first housing part 12 and the second housing part 16 are manufactured from a metal, e.g., aluminum or steel, and are at ground potential during operation of the gas-insulated switchgear assembly. Instead of one interrupter unit 14, it is also possible for a plurality of, for example four, interrupter units to be used which are connected in series with one another.

The first housing part 12 and the second housing part 16 are each provided at both ends with connecting end regions 20, 21, 22, 23, which make it possible to couple the first housing part 12 to the second housing part 16. For this purpose, the connecting end regions 20, 21, 22, 23 each have lateral connection pieces 24, 25, 26, 27 with flanges. The first housing part 12 and the second housing part 16 are substantially tubular between the connecting end regions 20, 21, 22, 23. The interrupter unit 14 is arranged within the substantially tubular section of the first housing part 12, with this interrupter unit 14 being arranged substantially along a first housing axis A1 defined by the tubular section. The closing resistor arrangement 18 is arranged within the substantially tubular section of the second housing part 16, with this closing resistor arrangement 18 being arranged substantially along a second housing axis A2 defined by the tubular section. The second housing part 16 is formed by two connecting elements 22′, 23′, which form the connecting end regions 22, 23, and by a tubular body 28 lying between the two connecting elements.

A known drive unit 30 is coupled to one connecting end region 20 of the first housing part 12 and is used to drive the interrupter unit 14 and a switch 32 for closing and opening the closing resistor arrangement 18. The switch 32 is arranged within that connecting end region 22 of the second housing part 16 which is closer to the drive unit 30. The mechanical connection between the drive unit 30 and the interrupter unit 14 is produced via a drive rod 34 made from insulating material, which drive rod 34 runs in the direction of the first housing axis A1. The mechanical connection between the drive unit 30 and the switch 32 is produced via a known mechanism (not illustrated).

The two connecting end regions 20, 21 of the first housing part 12 each have an outgoing connection piece 36, by means of which the high-voltage circuit breaker 10 can be connected to further elements of a gas-insulated switchgear assembly. The outgoing connection pieces 36 are arranged laterally with respect to the first housing axis A1, opposite the connection pieces 24, 25.

In order to electrically connect the high-voltage circuit breaker 10 to further elements of the gas-insulated switchgear assembly, a conductor 40, which is held spaced apart from the first housing part 12 by means of known insulation elements (not illustrated), runs through the outgoing connection piece 36 of the drive-side connecting end region 20. The conductor 40 runs from the opening of the outgoing connection piece 36 to the switch 32. The conductor 40 is electrically connected to a movable switching contact 46 of the switch 32 and to the interrupter unit 14.

A fixed switching contact 48 of the switch 32 which interacts with the movable switching contact 46 so as to close the switch 32 is arranged within the drive-side connecting element 22′ of the second housing part 16. A conductor 41 runs from the fixed switching contact 48 through the drive-side connecting element 22′ of the second housing part 16 and connects the fixed contact 48 to a first connecting contact 50 of the closing resistor arrangement 18.

A second terminal contact 52 of the closing resistor arrangement 18 is connected to a conductor 43 via a further conductor 42, which runs through the connecting element 23′ of the second housing part 16, which conductor 43 runs from the connection piece 25 of that connecting end region 21 of the first housing part 12 which faces away from the drive 30 to the outgoing connection piece 36 of said connecting end region 21. The interrupter unit 14 is likewise connected to this conductor 43. The conductors 40, 41, 42, 43 are held within the first or second housing part 12, 16 by means of known, disk-shaped or conical insulators in such a way that they are spaced as uniformly apart as possible from the first or second housing part 12, 16 in the radial direction with respect to the conductor 40, 41, 42, 43.

As another exemplary arrangement of the interrupter unit 14 in the first housing part 12 and the closing resistor arrangement 18 in the second housing part 16 shown in FIG. 1, the interrupter unit and the closing resistor arrangement can also be arranged in a common housing part, for example in the abovedescribed first housing part, in this case the second housing part no longer being required. The routing of the conductors must be matched to this arrangement.

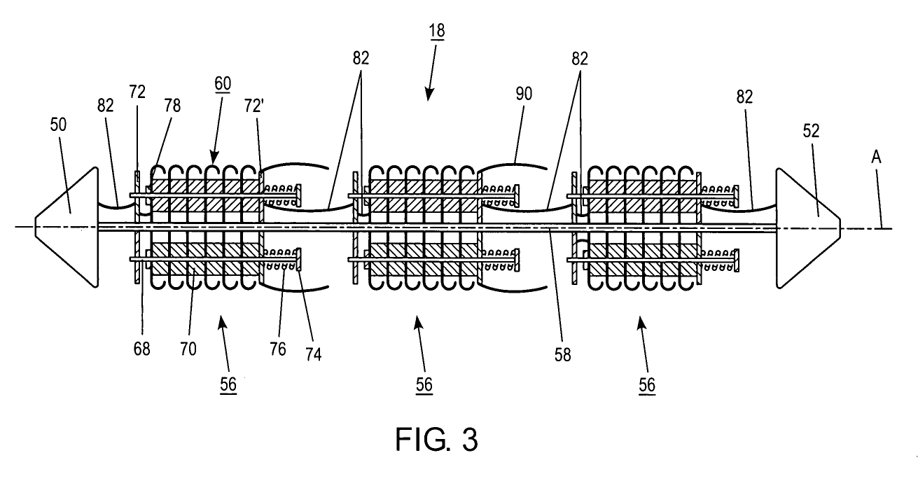

The closing resistor arrangement 18 shown in FIGS. 1 and 3 in the present exemplary embodiment comprises three active groups 56, which are arranged along the second housing axis A2 and in series with one another. Depending on the design of the closing resistor arrangement 18, another number of active groups can also be selected, in particular also a single active group. A central axis A of the closing resistor arrangement 18 coincides with the second housing axis A2. The three active groups 56 are positioned on a support tube 58 made from insulating material which runs along the central axis A and are held in position and supported by it. In each case one of the two terminal contacts 50, 52 is arranged at the two end regions of the support tube 58. The terminal contacts 50, 52 are fixedly connected to the conductor 41 or to the conductor 42, with the result that the closing resistor arrangement 18 is supported by the conductors 41, 42. The terminal contacts 50, 52 are manufactured from a highly conductive material such as aluminum, for example. In addition to their function as terminal contacts 50, 52, they are also used for shielding the closing resistor arrangement 18 in the direction of the second housing axis A2 or the central axis A.

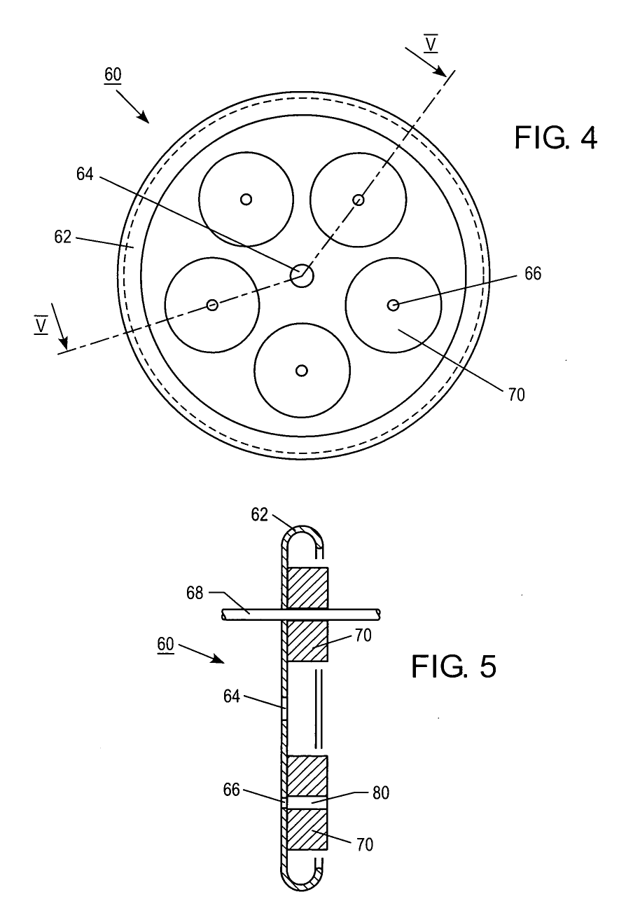

Each of the active groups 56 illustrated in FIGS. 1 and 3 has a large number of cooling elements 60 which are arranged in series with one another. As is shown in particular in FIGS. 4 and 5, each cooling element 60 has a round shape which is planar in the central region, the outer marginal region 62 of the cooling element 60 being bent back out of the plane in such a way that the cooling element 60 is in the form of a C in cross section (see FIG. 5). In the center, each cooling element 60 has a passage hole 64, through which the support tube 58 is passed. The diameter of the passage hole 64 is selected to be greater than the diameter of the support tube 58, with the result that the cooling elements 60 are spaced apart from the support tube 58 or are capable of being displaced along the support tube 58 at least with a sufficiently large amount of play. The support tube 58 runs at right angles with respect to the plane of each cooling element 60.

The cooling element 60 is manufactured from metal, e.g., from aluminum, and has a plate-like shape. The wall thickness of the cooling element 60 is, for example, less than 5 mm, preferably less than 3 mm or less than 1 mm. The diameter of the cooling element 60 is, for example, between 30 cm and 150 cm and preferably between 80 cm and 120 cm. For example, the flat extent of the cooling element 60 is typically 2 to 3 orders of magnitude greater than the wall thickness of the cooling element 60.

Furthermore, each cooling element 60 has five installation holes 66, which are arranged at equal distances from one another on a circle (not shown). The center point of this circle is congruent with the center point of the passage hole 64. The radius of the circle is selected in such a way that the circle is positioned substantially centrally between the passage hole 64 and the marginal region 62.

The cooling elements 60 of each active group 56 are aligned with respect to one another in such a way that the five installation holes 66 and the passage hole 64 of each cooling element 60 are in each case congruent in the direction of the central axis A. In each case one rod 68, which is manufactured from an insulating material, is passed through the installation holes 66 which are aligned with one another.

In each case five resistor elements 70 are arranged between two cooling elements 60 of each active group 56, which cooling elements 60 are adjacent in the direction of the central axis A. Each of the five resistor elements 70 is held by one of the five rods 68.

In order to hold the active groups 56 on the support tube 58, each active group 56 has two round support plates 72, 72′, which are supported by the support tube 58 and for their part support the rods 68 of each active group 56. The rods 68 support the cooling elements 60 and the resistor elements 70. The two support plates 72, 72′ each have a hole in the center, through which hole the support tube 58 is passed and the support plate 72, 72′ is held fixedly on the support tube 58. Furthermore, each support plate 72, 72′, similarly to the cooling elements 60, has five installation holes 66, through which in each case one of the rods 68 is passed and is held in the circumferential direction as well as in the radial direction. In the direction of the central axis A, the rod 68 is passed movably through the support plate 72, 72′. The abovedescribed resistor elements 70 and cooling elements 60 are arranged between the two support plates 72, 72′ of each active group 22.

In turn five resistor elements 70, which are each supported by one of the rods 68, is arranged between one support plate 72′ of each active group 22 and the cooling element 60 which adjoins this support plate 72′. A helical spring 76 is positioned onto the rod 68 between this support plate 72′ and a thickened end region 74 of each rod 68 on this side.

In total five prestressing rings 78 are arranged between the other support plate 72 of each active group 56 and the cooling element 60 adjoining this support plate 72, in each case one prestressing ring 78 being held fixedly on each rod 68. In each case one of these prestressing rings 78 interacts with the thickened end region 78 of the rod 68 and of the helical spring 76 in such a way that the cooling elements 60 arranged between the prestressing ring 78 and the thickened end region 74, the resistor elements 70 and one support plate 72′ bear fixedly against one another in the direction of the rod 68. This means that a good electrical and thermal connection is ensured between the cooling elements 60 and the resistor elements 70. Furthermore, this arrangement is used for compensating for a length extension as a result of thermal expansion, in particular the length extension of the resistor elements 70, by means of the spring 76.

The resistor elements 70 are manufactured, for example, from a sintered material and are generally known under the designation ceramic carbon resistor. Each resistor element 70 has a straight, circular-cylindrical shape, the resistor element 70 having a through-hole 80 along its cylinder axis. The inner diameter of this through-hole 80 corresponds to the inner diameter of the installation holes 66 of the cooling element 60. The through-hole 80 of the resistor element 70 is used for holding said resistor element 70 in position on the rod 68 in the radial direction. For this purpose, the rod 68 is passed through the through-hole 80. The two end faces of each resistor element 70 are in the form of contacts and for this purpose can have a coating made from a highly electrically conductive material and are used for producing the electrical connection with the adjacent cooling elements 60 or with the adjacent support plate 72′. Furthermore, the connection between the resistor element 70 and the cooling element 60 has a high thermal conductivity, with the result that heat from the resistor element 70 can be dissipated to the cooling elements 60.

The outer diameter of the resistor elements 70 is selected to be as large as possible, but only so large that they do not touch either the adjacent resistor elements 70, the support tube 58 or the outer marginal region 62 of the cooling element 60. Consequently, each resistor element 70 touches the adjacent cooling element 60 within a contact region, the cooling element 60 protruding beyond the contact region and therefore beyond the resistor element 70 in the direction of the plane defined by the central region of the cooling element 60. This means that the heat is conducted from the resistor elements 70 via the contact region of the cooling elements 60 into regions of the cooling elements 60 against which no resistor elements 70 bear. In particular, the heat is dissipated into the outer marginal regions 62. The heat can be emitted radially outwards in particular from the outer marginal region 62.

The three active groups 56 of the closing resistor arrangement 18 which are arranged in series on the support tube 58 are connected electrically in series with one another. For this purpose, the two terminal contacts 50, 52 are connected to the adjoining support plate 72, 72′ via in each case one wire 82. The electrical connection of the active groups 56 to one another is likewise produced via wires 82, which connect adjacent support plates 72, 72′ of adjacent active groups 56 to one another. Furthermore, in each active group 56 a wire 82 connects the support plate 72, which is arranged within the active group 56 away from the thickened end region 74 of the insulating bar 68, to the adjacent cooling element 60.

In order to shield the wire 82 between the active groups 56, a convex shielding plate 90 is integrally formed on each support plate 72′ and shields the springs 76, the thickened end regions 74 and the wire 82 radially.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

10 High-voltage circuit breaker
12 First housing part
14 Interrupter unit
16 Second housing part
18 Closing resistor arrangement
20-23 Connecting end regions
22′, 23′ Connecting elements
24-27 Connection pieces
28 Tubular body
30 Drive unit
32 Switch
34 Drive rod
36 Outgoing connection piece
40-43 Conductors
46 Movable switching contact
48 Fixed switching contact
50 First terminal contact
52 Second terminal contact
56 Active group
58 Support tube
60 Cooling element
62 Outer marginal region
64 Passage hole
66 Installation hole
68 Rods
70 Resistor element
72, 72′ Support plate
74 End region
76 Helical spring
78 Prestressing discs
80 Through-hole
82 Wire
90 Shielding plate
A Central axis
A1 First housing axis
A2 Second housing axis

What is claimed is:

1. A closing resistor arrangement for a high-voltage circuit breaker with a large number of resistor elements and a large number of connecting elements, the connecting elements being arranged in series with one another and at least one of the resistor elements being arranged between at least two connecting elements which are arranged in series for the serial electrical connection of these connecting elements, wherein the connecting elements which are electrically connected to one of the resistor elements are in the form of a cooling element for the purpose of dissipating heat from the resistor element, wherein two cooling elements which are arranged in series with one another are electrically connected to one another by means of a resistor element and wherein a plurality of resistor elements are arranged parallel to one another between two cooling elements and are connected electrically in parallel with one another by the cooling elements.

2. The closing resistor arrangement as claimed in claim 1, wherein each of the cooling elements is flat, is thermally connected to the adjoining resistor element in a contact region and protrudes beyond this contact region for the purpose of dissipating the heat from the contact region.

3. The closing resistor arrangement as claimed in claim 1, wherein the individual cooling elements each have a substantially round shape which is planar within an outer marginal region and the outer marginal region of each cooling element is designed to be bent back out of the plane of the central region for electrical shielding and/or cooling purposes.

4. The closing resistor arrangement as claimed in claim 1, wherein the cooling elements are manufactured from metal, and have a thickness of less than 5 mm.

5. The closing resistor arrangement as claimed in claim 1, wherein the closing resistor arrangement has an active group comprising resistor elements and cooling elements, the active group having a number of rods which corresponds to the number of resistor elements which are arranged parallel to one another, which rods are arranged parallel to one another and are used for connecting the cooling elements and the resistor elements mechanically to one another, the resistor elements which are arranged parallel to one another being supported by the rods which are arranged parallel to one another, and the rods being supported at end regions on both sides by in each case one support plate on a common support tube of the closing resistor arrangement.

6. The closing resistor arrangement as claimed in claim 5, wherein a plurality of active groups are arranged on the support tube and are connected electrically in series with one another.

7. A high-voltage circuit breaker with a closing resistor arrangement as claimed in claim 1.

8. The high-voltage circuit breaker as claimed in claim 7, wherein the closing resistor arrangement is connected in parallel with an interrupter unit of the circuit breaker.

9. The high-voltage circuit breaker as claimed in claim 8, wherein the interrupter unit is arranged within a first housing part of the high-voltage circuit breaker, and the closing resistor arrangement is arranged within a second housing part of the high-voltage circuit breaker, the first housing part and the second housing part being connected to one another at connecting end regions of the first housing part and of the second housing part.

10. The high-voltage circuit breaker as claimed in claim 7, wherein an interrupter unit of the high-voltage circuit breaker and the closing resistor arrangement are arranged within the same housing part of the high-voltage circuit breaker.

11. The closing resistor arrangement as claimed in claim 2, wherein the individual cooling elements each have a substantially round shape which is planar within an outer marginal region and the outer marginal region of each cooling element is designed to be bent back out of the plane of the central region for electrical shielding and/or cooling purposes.

12. The closing resistor arrangement as claimed in claim 2, wherein the cooling elements are manufactured from aluminum, and have a thickness of less than 2 mm.

13. The closing resistor arrangement as claimed in claim 3, wherein the cooling elements are manufactured from aluminum, and have a thickness of less than 1 mm.

14. The closing resistor arrangement as claimed in claim 4, wherein the closing resistor arrangement has an active group comprising resistor elements and cooling elements, the active group having a number of rods which corresponds to the number of resistor elements which are arranged parallel to one another, which rods are arranged parallel to one another and are used for connecting the cooling elements and the resistor elements mechanically to one another, the resistor elements which are arranged parallel to one another being supported by the rods which are arranged parallel to one another, and the rods being supported at end regions on both sides by in each case one support plate on a common support tube of the closing resistor arrangement.

15. A high-voltage circuit breaker with a closing resistor arrangement as claimed in claim 6.

16. The high-voltage circuit breaker as claimed in claim 8, wherein an interrupter unit of the high-voltage circuit breaker and the closing resistor arrangement are arranged within the same housing part of the high-voltage circuit breaker.

17. A closing resistor arrangement for a high voltage circuit breaker, comprising:
a plurality resistor elements; and
a plurality of cooling elements, the cooling elements being arranged in series with one another and being connected electrically in series with one another, wherein the resistor elements electrically connect the electrical cooling elements to one another.

18. The closing resistor arrangement as claimed in claim 17, wherein the resistor elements are arranged in each case between two cooling elements which are arranged in series.
